(19) United States
(12) Patent Application Publication
(10) Pub. No.: US 2003/0003710 A1
(43) Pub. Date: Jan. 2, 2003

(54) Method of making a semiconductor device that includes a dual damascene interconnect

(76) Inventor: Anjaneya Modak, Sunnyvale, CA (US)

Correspondence Address: Michael A. Bernadicou, BLAKELY, SOKOLOFF, TAYLOR & ZAFMAN LLP, Seventh Floor, 12400 Wilshire Boulevard, Los Angeles, CA, 90025-1026, US

(21) Appl. No.: 09/895,676

(22) Filed: Jun. 29, 2001

(51) Int. Cl. H01L 21/4763

(52) U.S. Cl. 438/625

(57) ABSTRACT

An improved method for making a semiconductor device is described. That method includes forming a first dielectric layer on a substrate, then etching a trench into the first dielectric layer. After filling the trench with a conductive material, a portion of the conductive material is removed to form a recessed conductive layer within the first dielectric layer. An upper barrier layer that comprises tantalum nitride and tantalum is then formed on the recessed conductive layer.

### FIELD OF THE INVENTION

The present invention relates to a method for making semiconductor devices, particularly those that include a dual damascene interconnect.

### BACKGROUND OF THE INVENTION

Dual damascene interconnects may enable reliable low cost production of high speed semiconductor devices using sub 0.25 micron process technology. A conventional process for making devices that include such an interconnect includes the following steps. A silicon nitride barrier layer is formed on a substrate, followed by depositing a dielectric layer onto it. A via and trench are then etched into the dielectric layer. A second barrier layer is formed to line the via and trench, followed by filling the via and trench with copper. After applying a chemical mechanical polishing (“CMP”) step to remove copper from the surface of the dielectric layer, the process is repeated with a layer of silicon nitride being deposited on the copper and the dielectric layer, followed by forming another dielectric layer on top of the silicon nitride layer, and so on.

As device features shrink, the distance between copper lines decreases, creating the need for a dielectric with a lower dielectric constant. Forming the dielectric layer from certain low-k materials serves to reduce the dielectric constant. The presence of silicon nitride, however, dilutes the dielectric constant lowering impact of such low-k materials because silicon nitride (with a relatively high dielectric constant) raises the effective dielectric constant for the intermetal dielectric stack. Using silicon nitride to form the barrier layer is problematic for another reason. The weak copper, silicon nitride interface may adversely affect electromigration performance and reliability. In addition, when using silicon nitride to form the barrier layer, an additional etch, ash, and clean sequence must be added to the process. Such extra process steps are necessary to remove the portion of that layer, which is located at the bottom of the via, to enable the copper that fills the via to contact the underlying copper line.

Accordingly, there is a need for a process for making a semiconductor device that includes a dual damascene interconnect, which has an intermetal dielectric with a lower dielectric constant. There is also a need for such a process that generates a semiconductor device that has a stronger copper/barrier layer interface. The present invention provides such a process.

### BRIEF DESCRIPTION OF THE DRAWINGS

FIGS. 1a-1g represent cross-sections of structures that may result when certain steps are used to carry out an embodiment of the method of the present invention.

### DETAILED DESCRIPTION OF THE PRESENT INVENTION

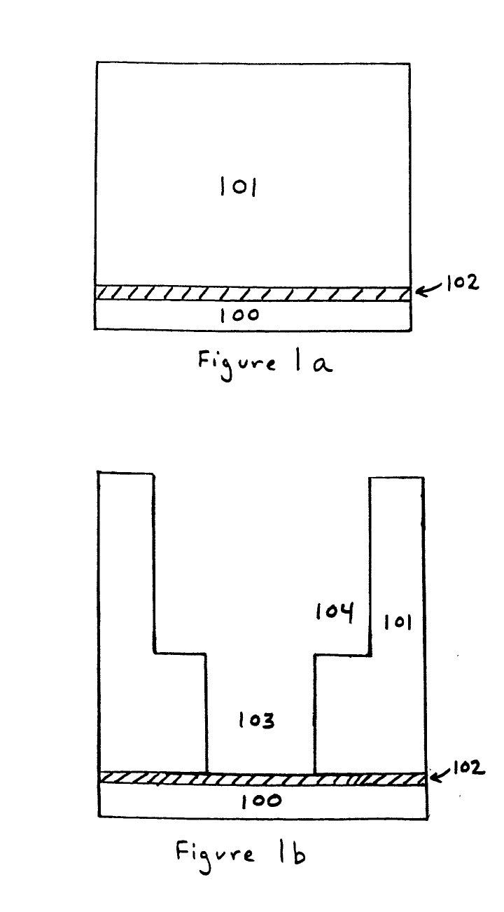

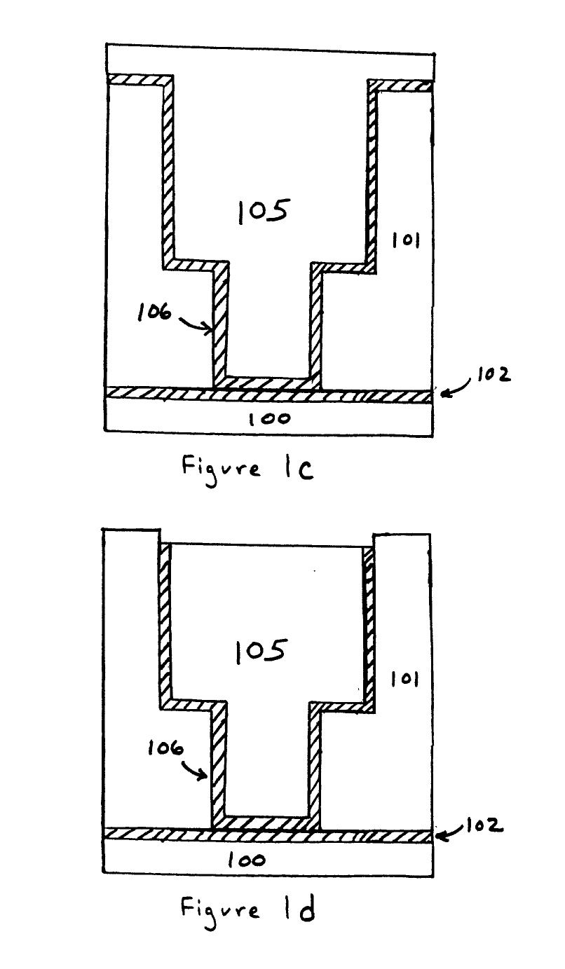

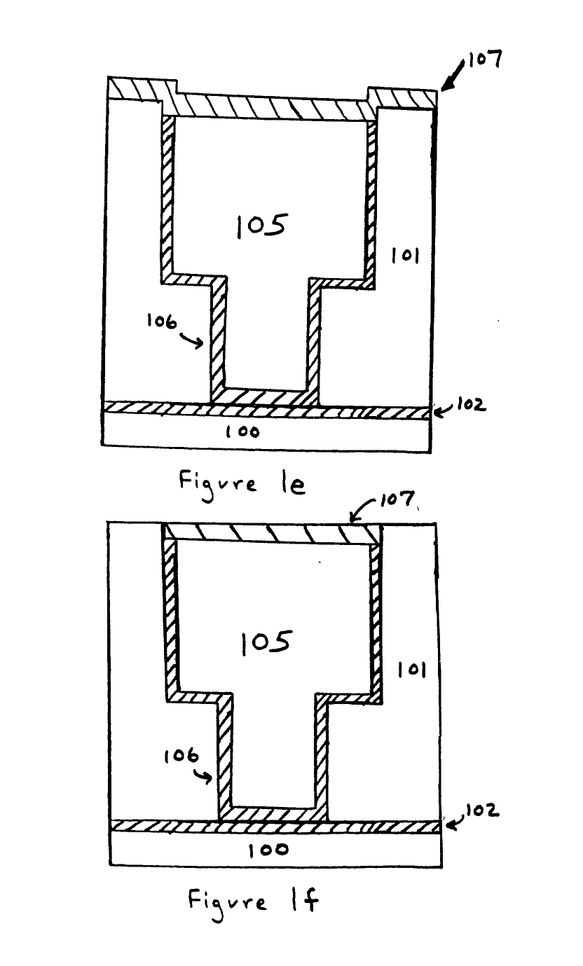

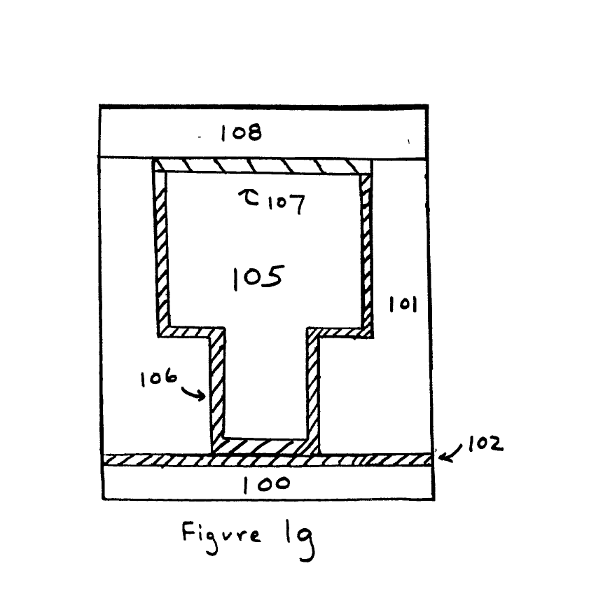

An improved method for making a semiconductor device is described. In that method, lower barrier layer 102 is formed on substrate 100, followed by forming first dielectric layer 101 on barrier layer 102, as shown in FIG. 1a. Substrate 100 may be any surface, generated when making a semiconductor device, upon which a dielectric layer may be formed. Substrate 100 thus may include, for example, active and passive devices that are formed on a silicon wafer such as transistors, capacitors, resistors, diffused junctions, gate electrodes, local interconnects, etc. . . . Substrate 100 also may include one or more conductive layers that are separated from each other, or from such active and passive devices, by one or more dielectric layers.

Barrier layer 102 will serve to prevent an unacceptable amount of copper, or other metal, from diffusing into dielectric layer 101. Barrier layer 102 may also act as an etch stop, protecting an underlying conductive layer during subsequent via and trench etch and cleaning steps. Although conventionally made from silicon nitride, or other materials that can serve such functions (e.g., silicon carbide, silicon oxycarbide or silicon oxynitride), in the method of the present invention barrier layer 102 preferably comprises a refractory material, such as tantalum, tantalum nitride or titanium nitride. Particularly preferred is a two layer stack that includes an underlying tantalum nitride layer upon which is formed a tantalum layer.

When comprising such a two layer stack, a conventional physical vapor deposition (“PVD”) process may be used to form barrier layer 102. Barrier layer 102 should be thick enough to perform its diffusion inhibition and etch stop functions, but not so thick that it adversely impacts the overall dielectric characteristics resulting from the combination of barrier layer 102 and dielectric layer 101. To balance these two factors, the thickness of barrier layer 102 preferably should be less than about 10% of the thickness of dielectric layer 101. In a preferred embodiment, barrier layer 102 preferably is between about 10 and 50 nanometers thick.

First dielectric layer 101 may comprise any material that may insulate one conductive layer from another. Preferred are insulating materials with a dielectric constant that is lower than the dielectric constant of silicon dioxide, e.g., porous oxide; carbon or fluorine doped oxide; organic containing silicon oxides; or various polymers. A particularly preferred material for making dielectric layer 101 is a fluorosilicate glass (“FSG”), which may be deposited onto barrier layer 102 using a conventional high density plasma (“HDP”) process.

When FSG is used to make dielectric layer 101, the capacitance between various conductive elements that are separated by layer 101 will be reduced, when compared to the capacitance resulting from use of conventionally used dielectric materials—such as silicon dioxide. Such reduced capacitance may decrease the RC delay that would otherwise exist and may also decrease undesirable cross-talk between conductive lines. This, in turn, should allow the device to operate at a higher speed.

First dielectric layer 101 may alternatively comprise an organic polymer. Such organic polymers include, for example, polyimides, parylenes, polyarylethers, organo-silicones, polynaphthalenes, and polyquinolines, or copolymers thereof. Commercially available polymers sold by Honeywell, Inc., under the trade name FLARE™, and by the Dow Chemical Company, under the trade name SiLK™, may be used to form first dielectric layer 101. When first dielectric layer 101 comprises a polymer, it is preferably formed by spin coating the polymer onto the surface of substrate 100 using conventional equipment and process steps.

First dielectric layer 101 may also be made from a compound having the molecular structure SiₓO_{y}R_{z}, in which R may be hydrogen, carbon, an aliphatic hydrocarbon or an aromatic hydrocarbon. When “R” is an alkyl or aryl group, the resulting composition is often referred to as carbon-doped oxide. When first dielectric layer 101 comprises a carbon-doped oxide, dielectric layer 101 preferably includes between about 5 and about 50 atom % carbon. More preferably, such a compound includes about 15 atom % carbon.

Examples of other types of materials that may be used to form dielectric layer 101 include aerogel, xerogel, and spin-on-glass (“SOG”). In addition, dielectric layer 101 may comprise either hydrogen silsesquioxane (“HSQ”), methyl silsesquioxane (“MSQ”), or other materials having the molecular structure specified above, which may be coated onto the surface of a semiconductor wafer using a conventional spin coating process. Although spin coating may be a preferred way to form layer 101 for some materials, for others a plasma enhanced chemical vapor deposition (“PECVD”) process may be preferred. First dielectric layer 101 preferably has a thickness of between about 100 and about 2,000 nanometers.

In the embodiment of the present invention described with reference to FIGS. 1a-1g, dielectric layer 101 comprises a single layer. In alternative embodiments, multiple layers of dielectric material may be deposited to form dielectric layer 101, e.g., to generate a dielectric stack that benefits from the different properties of the different materials.

After forming dielectric layer 101 on barrier layer 102, a series of conventional lithographic, etching and cleaning steps may be applied to produce the structure represented by FIG. 1b, in which via 103 and trench 104 have been etched into dielectric layer 101. After the via and trench are etched, barrier layer 106 is formed, which lines the via and trench bottom and walls.

Barrier layer 106 will block diffusion into dielectric layer 101 of copper (or other elements) that will subsequently fill via 103 and trench 104. Barrier layer 106 preferably comprises a refractory material, such as tantalum, tantalum nitride or titanium nitride, but may be made from other materials that can inhibit diffusion of copper into dielectric layer 101. Barrier layer 106, like barrier layer 102, preferably comprises a tantalum nitride, tantalum stack, which may be deposited onto the sides of the via and the trench using essentially the same process used to deposit barrier layer 102 onto substrate 100. Barrier layer 106 preferably is between about 10 and 50 nanometers thick (with the tantalum nitride layer preferably being thicker than the overlying tantalum layer), and preferably is formed using a conformal PVD process. (Alternatively, a PECVD process may be used to form barrier layer 106.)

After forming barrier layer 106, via 103 and trench 104 are filled with a conductive material to form conductive layer 105, which is formed on barrier layers 102 and 106. This generates the structure shown in FIG. 1c. Conductive layer 105 may be made from materials conventionally used to form conductive layers for semiconductor devices, and is preferably made from copper. When copper forms conductive layer 105, a conventional copper electroplating process may be used. Such a process typically comprises depositing a barrier layer (e.g., barrier layer 106 shown in FIG. 1c) followed by depositing a seed material (e.g., one made of copper), then performing a copper electroplating process to produce the copper line, as is well known to those skilled in the art.

In a typical process, after conductive layer 105 is deposited, it is polished, e.g, by applying a CMP step, until its surface is substantially flush with (or recessed slightly below) the surface of dielectric layer 101. (That polishing step may be followed by a standard cleaning step.) In, however, one embodiment of the process of the present invention, a significantly greater amount of conductive layer 105 is removed, without simultaneously removing significant amounts of dielectric layer 101, to form a relatively highly recessed conductive layer within layer 101.

There are many ways to remove additional amounts of conductive layer 105 without removing a substantial portion of dielectric layer 101. For example, an electropolish process may be applied to generate a recessed conductive layer. Such a process will generally require that electrical contact be maintained to conductive layer 105. In the embodiment described here, electrical contact may be maintained with conductive layer 105 because layer 105 is formed on a dissimilar, relatively thin, conductive layer that lines the trench—i.e., barrier layer 106.

The electropolish process itself is well known to those skilled in the art, consisting essentially of contacting the surface to be polished with an appropriate solution chemistry, then applying an electrical potential to that surface. See, e.g., R. Contolini, A. Bernhardt, and S. Mayer, Electrochemical Planarization for Multilevel Metallization, J. Electrochem. Soc., Vol. 141, No. 9, pp. 2503-2510 (September 1994). Such a process may enable the controlled, selective removal of copper from the surface of a copper layer. In one example, portions of a copper layer may be removed by exposing that layer's surface to a phosphoric acid containing solution, then applying an electrical potential of between about 1 and about 1.5V (with respect to a copper reference electrode) for a period of time sufficient to remove the desired amount of copper from the copper layer. The electrical potential may be applied in a steady state fashion, or alternatively, in a dynamic fashion—e.g., by using pulsed plating. Preferably, current density is maintained between about 15 and about 20 mA/cm².

In this embodiment of the present invention, conductive layer 105 must be recessed sufficiently deep into dielectric layer 101 to ensure that a subsequently deposited barrier layer will maintain a sufficient thickness to serve as a barrier layer and etch stop, even after the barrier layer has been polished and cleaned. In a preferred embodiment, conductive layer 105 is polished until its upper surface is separated from the surface of dielectric layer 101 by at least about 10 nanometers, and more preferably by at least about 50 nanometers.

Alternatively, a relatively highly recessed conductive layer may be formed by adjusting the parameters applied during the CMP process, such as by enhancing the chemical etch contribution to the polishing process near the end of that treatment. A standard cleaning step may follow such a modified polishing step. Such a recessed conductive layer may also be formed by applying a selective wet etch process (which follows a conventional CMP polish and clean sequence) to etch the copper at a significantly faster rate than it etches dielectric layer 101. Removing a portion of conductive layer 105 (along with the adjacent part of barrier layer 106), without simultaneously removing a significant portion of dielectric layer 101, produces the structure shown in FIG. 1d.

After forming recessed conductive layer 105, a two step process may follow to form upper barrier layer 107 to completely encapsulate conductive layer 105. First, layer 107 (like layer 106 preferably a two layer stack comprising a tantalum nitride layer upon which a tantalum layer is formed) is deposited over dielectric layer 101 and conductive layer 105 using, for example, a conventional PVD process. Layer 107 should be deposited at an adequate thickness such that between about 10 and about 50 nanometers of that layer remain on top of conductive layer 105, after layer 107 is removed from the surface of dielectric layer 101. The resulting structure is shown in FIG. 1e.

Next, the portions of layer 107 that cover dielectric layer 101 are removed. In a preferred embodiment, those portions are removed using a conventional CMP step. To minimize the degree to which layer 107 is etched beneath the surface of dielectric 101, it may be desirable to apply a CMP process that uses a relatively hard polishing pad, and to design the process such that mechanical removal dominates over chemical removal. Reducing recession of layer 107 below dielectric layer 101's surface may be necessary to enable layer 107 to perform as an effective barrier layer.

After removing layer 107 from dielectric layer 101, the resulting structure includes upper barrier layer 107 formed on conductive layer 105, as shown in FIG. 1f. Upper barrier layer 107, like barrier layers 102 and 106, will serve to prevent an unacceptable amount of copper, or other metal, from diffusing from conductive layer 105 into any overlying dielectric layer. To perform that function, barrier layer 107 preferably is between about 10 and about 50 nanometers thick. The optimal thickness will, of course, depend upon the thickness required to provide this barrier function for a particular application.

As an alternative to forming a highly recessed conductive layer, then filling the recess with barrier layer 107 to form the FIG. 1f structure, the following process sequence may be used. Conductive layer 105 is polished and cleaned in the usual way. Barrier layer 107 is then deposited on the surface of conductive layer 105 and dielectric layer 101. The portion of barrier layer 107 that covers conductive layer 105 is masked while the portion that covers dielectric layer 101 is exposed, using a conventional photolithography process. The exposed portion is then removed, e.g., by applying a conventional dry etch process. Although the resulting structure will include portions of barrier layer 107 that rise above the surface of dielectric layer 101 (in contrast to the embodiments described above), subsequent processing of the dielectric layer that will be deposited on the barrier layer can eliminate any discontinuity in the surface of that subsequently deposited dielectric layer.

After forming upper barrier layer 107, second dielectric layer 108 may be deposited on its surface, as shown in FIG. 1g. Layer 108, like layer 101, preferably has a low dielectric constant, and is preferably made from FSG using a HDP process. (A relatively thin undoped silicon dioxide layer, made using a HDP process, may be formed between the FSG layers and the barrier layers—if desired to minimize reaction between FSG and tantalum.) The same materials, process steps and equipment used to form layer 101 may be used to form layer 108. Alternatively, different materials may be used to form those two layers. In the resulting structure, barrier layers 102, 106 and 107 completely surround conductive layer 105. When these layers all comprise a two layer tantalum nitride, tantalum stack, they will serve to reduce the dielectric constant for the intermetal dielectric, when compared to structures that use silicon nitride to form at least one of these barrier layers. After forming layer 108, a via (not shown) may be etched through it down to barrier layer 107. The process steps described above may be repeated as necessary to generate a device with the desired number of metal levels.

As shown in FIG. 1g, the semiconductor device made by this embodiment of the method of the present invention includes the following features. Conductive layer 105, preferably comprising copper, is formed on lower barrier layer 102, which in turn is formed on substrate 100. Conductive layer 105 is enclosed by barrier layers 102, 106, and 107.

The method of the present invention, which forms upper barrier layer 107 from a tantalum nitride, tantalum stack, generates a structure with an intermetal dielectric that has a relatively low dielectric constant, when compared to structures that include a silicon nitride barrier layer. Moreover, by forming a barrier layer that includes these materials, the interface between the conductive layer and the barrier layer is strengthened. Such a method thus enables the resulting device to have improved RC properties, while improving that interface.

As mentioned above, when silicon nitride is used to form either barrier layer 102 or barrier layer 107, it may be necessary to remove the portion of the barrier layer that separates a via from a conductive layer that lies below the via. Such a removal step may be needed to ensure good contact between the conductive layer and the conductive material used to fill the via. In contrast, when the barrier layer is formed from a tantalum nitride, tantalum stack, sufficient contact may result between the conductive material that is deposited on top of that stack and the conductive layer that lies beneath the stack. As a result, when a tantalum nitride, tantalum stack is used to form the barrier layer, extra steps are not required to remove the barrier layer from the bottom of the via. This provides a simplified process, when compared to processes that use silicon nitride to form the barrier layer.

Features shown in the above referenced drawings are not intended to be drawn to scale, nor are they intended to be shown in precise positional relationship. Additional steps that may be included in the above described method have been omitted as they are not useful to describe aspects of the present invention.

Although the foregoing description has specified certain steps, materials, and equipment that may be used in such a method to make a semiconductor device, those skilled in the art will appreciate that many modifications and substitutions may be made. Note that although the embodiment described with reference to FIGS. 1a-g shows only one conductive layer, the number of conductive and dielectric layers included in the resulting semiconductor device may vary, as is well known to those skilled in the art. In this regard, the process described above may be repeated to form additional conductive and insulating layers until the desired semiconductor device is produced. Accordingly, it is intended that all such modifications, alterations, substitutions and additions be considered to fall within the spirit and scope of the invention as defined by the appended claims.

What is claimed is:

1. A method of making a semiconductor device comprising:
forming a first dielectric layer on a substrate;
etching a trench into the first dielectric layer;
filling the trench with a conductive material;
removing a portion of the conductive material to form a recessed conductive layer within the first dielectric layer; and
forming on the recessed conductive layer an upper barrier layer that comprises tantalum nitride and tantalum.

2. The method of claim 1 wherein the conductive material comprises copper.

3. The method of claim 2 further comprising lining the trench with a first barrier layer prior to filling it with the conductive material.

4. The method of claim 3 further comprising forming a second dielectric layer on the surface of the first dielectric layer and the upper barrier layer.

5. The method of claim 4 wherein the upper barrier layer is formed by depositing a tantalum nitride layer on the surface of both the recessed conductive layer and the first dielectric layer, depositing a tantalum layer on the tantalum nitride layer, then removing both the tantalum nitride layer and the tantalum layer from the surface of the first dielectric layer.

6. The method of claim 5 further comprising forming a lower barrier layer on the substrate then forming the first dielectric layer on the lower barrier layer.

7. A method of making a semiconductor device comprising:
forming a first barrier layer on a substrate;
forming a first dielectric layer on the first barrier layer;
etching a via into the first dielectric layer;
etching a trench into the first dielectric layer;
lining the via and trench with a second barrier layer;
filling the via and trench with a conductive material;
removing a portion of the conductive material to form a recessed conductive layer within the first dielectric layer; and
forming on the recessed conductive layer a third barrier layer that comprises tantalum nitride and tantalum.

8. The method of claim 7 wherein the conductive material comprises copper, the first barrier layer comprises tantalum nitride and tantalum, and the second barrier layer comprises tantalum nitride and tantalum.

9. The method of claim 8 further comprising forming a second dielectric layer on the surface of the first dielectric layer and the third barrier layer.

10. The method of claim 9 wherein the third barrier layer is formed by depositing a tantalum nitride layer on the surface of both the recessed conductive layer and the first dielectric layer, depositing a tantalum layer on the tantalum nitride layer, then applying a chemical mechanical polishing step to remove both the tantalum nitride layer and the tantalum layer from the surface of the first dielectric layer.

11. The method of claim 9 wherein the third barrier layer is formed by:
depositing a tantalum nitride layer on the surface of both the recessed conductive layer and the first dielectric layer;
depositing a tantalum layer on the tantalum nitride layer;
depositing, then patterning, a layer of photoresist such that it masks the tantalum nitride layer and the tantalum layer where it covers the recessed conductive layer; then
etching the tantalum nitride layer and the tantalum layer from the surface of the first dielectric layer while retaining those layers where they cover the recessed conductive layer.

12. The method of claim 10 wherein the recessed conductive layer is formed by applying a chemical mechanical polishing step to remove a portion of the conductive material followed by applying a cleaning step to remove residues that the chemical mechanical polishing step generated.

13. The method of claim 10 wherein the recessed conductive layer is formed by applying a selective wet etch process that removes the conductive material at a substantially faster rate than it removes the first dielectric layer.

14. A semiconductor device comprising:
a first barrier layer formed on a substrate;
a first dielectric layer formed on the first barrier layer;
a second barrier layer that lines a via and trench, which have been etched into the first dielectric layer;
a conductive material that fills the via and trench, the conductive material having a substantially planarized upper surface that is located below the surface of the first dielectric layer; and
a third barrier layer that comprises tantalum nitride and tantalum that is formed on the substantially planarized upper surface of the conductive layer, such that the upper surface of the third barrier layer is substantially flush with the surface of the first dielectric layer.

15. The semiconductor device of claim 14 wherein the conductive material comprises copper, the first barrier layer comprises tantalum nitride and tantalum, and the second barrier layer comprises tantalum nitride and tantalum, such that the conductive layer is encapsulated by these three barrier layers that each comprise tantalum nitride and tantalum.

16. The semiconductor device of claim 15 further comprising a second dielectric layer that is formed on the surface of the first dielectric layer and the third barrier layer.

17. The semiconductor device of claim 16 wherein the third barrier layer is between about 10 and about 50 nanometers thick.

18. The semiconductor device of claim 17 wherein the first dielectric layer comprises a fluorosilicate glass.
